(19) United States
(12) Patent Application Publication
(10) Pub. No.: US 2016/0356866 A1
(43) Pub. Date: Dec. 8, 2016

(54) Embedded Sensor Systems

(71) Applicant: United Technologies Corporation, Farmington, CT (US)

(72) Inventors: Paul Attridge, East Hartford, CT (US); Nicholas Charles Soldner, Southbury, CT (US); Joseph V. Mantese, Ellington, CT (US); Cagatay Tokgoz, South Windsor, CT (US); Xin Wu, East Hartford, CT (US); Michael A. Klecka, Vernon, CT (US); Joseph Zacchio, Wethersfield, CT (US)

(21) Appl. No.: 14/728,473

(22) Filed: Jun. 2, 2015

(51) Int. Cl. G01R 33/12; G01R 33/00; G01R 33/02

(52) U.S. Cl. CPC G01R 33/12; G01R 33/02; G01R 33/0052; B33Y 10/00

(57) ABSTRACT

A sensing system may comprise a reader device including a primary magnetic coil, and a sensing device including a secondary magnetic coil and a sensing platform configured to acquire sensing data. The sensing system may further include a first part having the sensing device embedded therein. The reader device and the sensing device may be configured to communicate over a non-contact wireless interface using low frequency wireless power transfer.

### GOVERNMENT CONTRACT

This invention was conceived under Government contract number DE-DE0012299 with the Department of Energy. The Government has rights in this invention.

### FIELD OF THE DISCLOSURE

The present disclosure generally relates to sensors, and more specifically, relates to sensing systems that are embedded in parts such as metallic parts.

### BACKGROUND

Sensors may be used in various industrial applications to monitor the operation and/or performance of specific parts of an industrial system, sections of the system, or the system as a whole. For example, temperature sensors, such as thermocouples, may be used monitor local temperatures at various positions of gas turbine engines. Other types of sensors used in industrial applications include, but are not limited to, accelerometers, strain sensors, pressure sensors, and speed sensors. The sensors may be digital sensors that provide digital data reporting on a property of the part or the environment of the part.

In many cases, the sensors may be attached to the surface of a part located in a region of interest in the industrial system. However, such surface exposed sensors may be subjected to wear caused by exposure to environmental elements. For this reason, many surface-exposed sensors may experience reduced performance, may require frequent maintenance, and may have significantly reduced lifetimes compared to the part itself. As a result, many sensors, such as thermocouples and accelerometers, may only be attached to the surface of the part for a short period of time to allow temporary testing and diagnostics.

In addition, many sensors may require multiple wires or batteries for power and electronic communication with other devices. The wires and/or batteries may be cumbersome and may interfere with the operation of the part or with other parts within the system. For example, sensor wires may become entangled when used on a moving or rotating part, such as an airfoil.

Clearly, there is a need for improved sensor systems that overcome the aforementioned problems.

### SUMMARY OF THE DISCLOSURE

In accordance with one aspect of the present disclosure, a sensing system is disclosed. The sensing system may comprise a reader device including a primary magnetic coil, and a sensing device including a secondary magnetic coil and a sensing platform configured to acquire sensing data. The sensing system may further include a first part having the sensing device embedded therein. The reader device and the sensing device may be configured to communicate over a non-contact wireless interface using low frequency wireless power transfer.

In another refinement, the sensing device may be embedded in the first part by additive manufacturing.

In another refinement, the first part may be a metallic part.

In another refinement, the reader device may be embedded in a second part.

In another refinement, the low frequency wireless power transfer may be provided by a magnetic flux linkage between the primary magnetic coil and the secondary magnetic coil. The magnetic flux linkage may penetrate through the first part.

In another refinement, the first part may be a non-stationary part, and the second part may be a stationary part.

In another refinement, the reader device may be configured to power the sensing device through the low frequency wireless power transfer.

In another refinement, the low frequency wireless power transfer may permit wireless data transfer between the sensing device and the reader device.

In another refinement, the sensing device may be configured to transmit the sensing data to the reader device by the low frequency wireless power transfer.

In another refinement, the sensing platform may include a printed circuit board (PCB) supporting a plurality of integrated circuits (ICs), and at least one of the ICs may be a sensor.

In another refinement, the sensor may be configured to detect at least one property associated with the first part, and the at least one property may be selected from temperature, g-force, strain, and angular position.

In accordance with another aspect of the present disclosure, a sensing system is disclosed. The sensing system may comprise a reader device that includes a primary magnetic coil, and a sensing device that includes a secondary magnetic coil and a sensing platform configured to acquire sensing data. The sensing system may further comprise a stationary part supporting the reader device, and a rotatable part having the sensing device embedded therein. The reader device and the sensing device may be configured to communicate over a non-contact wireless interface using low frequency wireless power transfer.

In another refinement, the sensing device may be embedded in the rotatable part by additive manufacturing.

In another refinement, the rotatable part may be a metallic part.

In another refinement, the reader device may be embedded in the stationary part by additive manufacturing.

In another refinement, the low frequency wireless power transfer may be provided by a magnetic flux linkage between the primary magnetic coil and the secondary magnetic coil, and the magnetic flux linkage may penetrate through the stationary part and the rotatable part.

In another refinement, the reader device may be powered by a battery or with hard wires.

In another refinement, the reader device may be configured to power the sensing device through the low frequency wireless power transfer.

In another refinement, the low frequency wireless power transfer may permit wireless data transfer between the sensing device and the reader device.

In accordance with another aspect of the present disclosure, a method for manufacturing a sensor system is disclosed. The method may comprise inserting a sensing device in a cavity of a part, wherein the sensing device includes a secondary magnetic coil and a sensing platform configured to acquire sensing data. The method may further comprise applying a cover over the cavity and the sensing device to provide an embedded sensing device, and allowing communication between a reader device and the embedded sensing device over a non-contact wireless interface using low frequency wireless power transfer.

These and other aspects and features of the present disclosure will be more readily understood when read in conjunction with the accompanying drawings.

### BRIEF DESCRIPTION OF THE DRAWINGS

FIG. 1 is schematic depiction of a sensing system in accordance with an embodiment.

FIG. 2 is a perspective view of an airfoil having the sensing system embedded in a base of the airfoil, constructed in accordance with an embodiment.

FIG. 3 is a cross-sectional view through the section 3-3 of FIG. 2, illustrating a sensing device embedded in a rotatable lower disk of the base and a reader device in a stationary upper disk of the base, constructed in accordance with an embodiment.

FIG. 4 is cross-sectional view similar to FIG. 3, but without the upper disk and without a metallic cover over the sensing device, constructed in accordance with an embodiment.

FIG. 5 is perspective view of the airfoil having thermocouple sensors embedded therein, constructed in accordance with an embodiment.

FIG. 6 is a cross-sectional view through the section 6-6 of FIG. 5, constructed in accordance with an embodiment.

FIG. 7 is an electromagnetic simulation showing a magnetic flux linkage between a primary magnetic coil and a secondary magnetic coil embedded in separate metal alloy parts, according to an embodiment.

FIG. 8 a flowchart depicting a series of steps that may be involved in manufacturing the sensing system, in accordance with an embodiment.

FIG. 9 is a picture of a magnetic core assembly, in accordance with an embodiment.

FIG. 10 is a picture of the magnetic core assembly of FIG. 9 inserted in a cavity of a metallic part, in accordance with an embodiment.

FIG. 11 is picture of the metallic part of FIG. 11 after covering the cavity and the magnetic core assembly with a metallic cover by additive manufacturing, in accordance with an embodiment.

It should be understood that the drawings are not necessarily drawn to scale and that the disclosed embodiments are sometimes illustrated schematically and in partial views. It is to be further appreciated that the following detailed description is merely exemplary in nature and is not intended to limit the invention or the application and uses thereof. In this regard, it is to be additionally appreciated that the described embodiment is not limited to use with airfoils. Hence, although the present disclosure is, for convenience of explanation, depicted and described as certain illustrative embodiments, it will be appreciated that it can be implemented in various other types of embodiments and in various other systems and environments.

### DETAILED DESCRIPTION

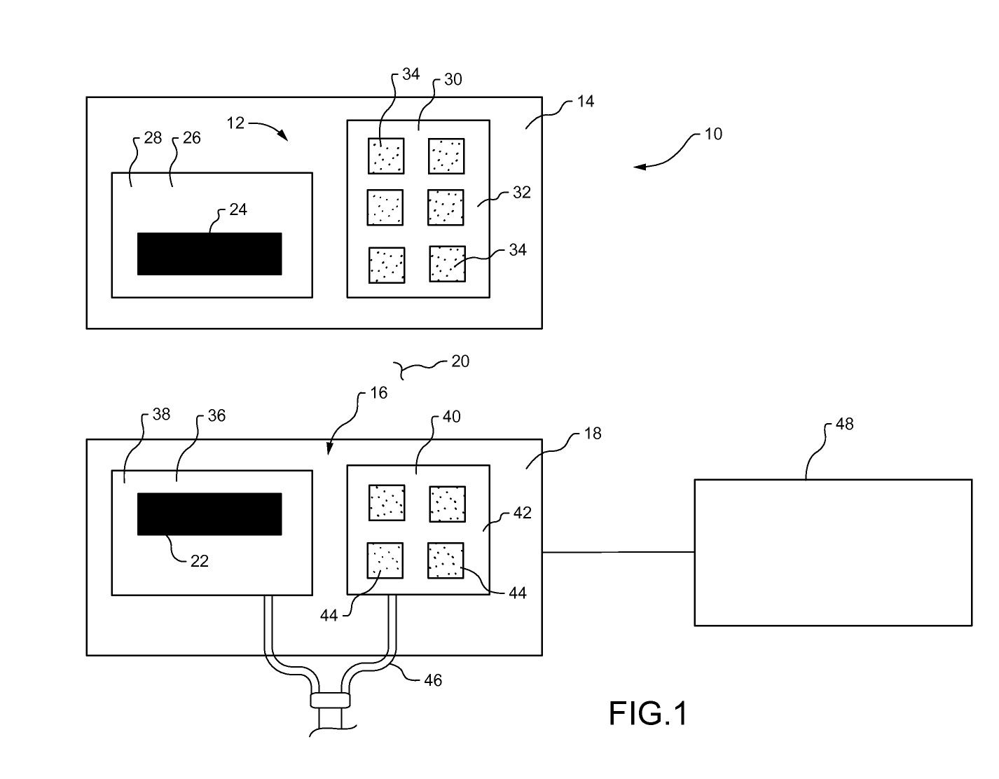

Referring now to the drawings, and with specific reference to FIG. 1, a sensing system 10 in accordance with an embodiment is depicted. The sensing system 10 may generally include a sensing device 12 that is partially or fully embedded in a first part 14 by additive manufacturing or another suitable process, and a reader device 16 which may be exposed or embedded in the same part 14 or in a second separate part 18. The first part 14 and the second part 18 may be made of metal, a metal alloy, or another suitable material. The sensing device 12 may be a digital sensor that detects at least one property associated with the part 14 or an environment of the part 14, such as temperature, pressure, speed, g-force, and angular position, among other possibilities. The sensing device 12 and the reader device 16 may be configured to communicate with each other over a non-contact wireless interface 20 via low frequency wireless power transfer. For example, the reader device 16 may be configured to provide power to the sensing device 12, as well as to share data (i.e., sensing data, commands, etc.) with the sensing device 12 over the non-contact interface 20. Specifically, a low frequency magnetic flux linkage between a primary magnetic coil 22 of the reader device 16 and a secondary magnetic coil 24 of the sensing device 12 may be configured to penetrate the metallic (or other) material of the parts 14/18, allowing the low frequency wireless communication over the non-contact interface 20 (see further details below).

The above arrangement may allow the sensing device 12 to be embedded in a non-stationary or moving part, such as a rotating part, without the need for cumbersome and entanglement-prone wires to provide power and data transmission. In addition, the embedment of the sensing device 12 in the part 14 may protect the sensing device 12 from exposure to environmental elements, and may reduce or eliminate wear and the need for maintenance/repair of the sensing device 12. In some cases, protection of the sensing device 12 in the part 14 may allow the sensing device 12 to last the lifetime of the part 14.

The sensing device 12 may include a core assembly 26 consisting of the secondary magnetic coil 24 encased or held in a ferromagnetic core 28 that may help to shape the path of the magnetic flux linkage with the primary magnetic coil 22. In addition, the sensing device 12 may also include a sensing platform 30 that may carry various sensors as well as other electronic components necessary for proper operation of the sensing system 10. For example, the sensing platform 30 may include a printed circuit board 32 supporting a plurality of integrated circuits (ICs) 34, or microchips. One or more of the ICs 34 may be a sensor such as, but not limited to, a temperature sensor (e.g., a thermocouple interface IC, etc.), an accelerometer, a strain sensor, and an angular position sensor. In some cases, the sensing platform 30 may support a plurality of different types of sensor ICs. The remaining ICs 34 on the PCB 32 may be various types of microchips that support the function of the circuitry of the sensing system 10 such as, but not limited to, rectifiers, microcontrollers, energy storage components, signal conditioning components, discrete tuning elements, capacitors, and processors as will be well-understood by those with ordinary skill in the art of digital sensors.

The reader device 16 may include a core assembly 36 consisting of the primary magnetic coil 22 encased or held in a ferromagnetic core 38 that may help to shape the path of the magnetic flux linkage with the secondary magnetic coil 24. The reader device 16 may also include a circuit platform 40 that may consist of a PCB 42 supporting various ICs 44 that support the function of the circuitry of the sensing system 10 such as, but not limited to, rectifiers, microcontrollers, energy storage components, and processors. In some cases, the reader device 16 may be embedded in the second part 18 by additive manufacturing or another suitable method or it may be exposed in air. In any event, the reader device 16 may be stationary such that it may be connected to and may receive power from one or more batteries or hard wires/cables 46 without interference from wire entanglement caused by part rotation.

In operation, the reader device 16 may receive power from one or more batteries or the wires 46, and may transfer power to the sensing device 12 via low frequency wireless power transfer. The reader device 16 may also transmit various commands or data to the sensing device 12 via low frequency wireless power transfer, such as commands to initiate or stop sensing data acquisition. In the same way, the sensing device 12 may transmit data, such as the acquired sensing data, to the reader device 16. The reader device 16 may be in electrical communication with a control center 48 and may transmit the sensing data to the control center 48. The control center 48 may automatically perform analysis and/or diagnostics of the sensing data, or may output the sensing data to a user interface for analysis and/or diagnostics by an operator or technician.

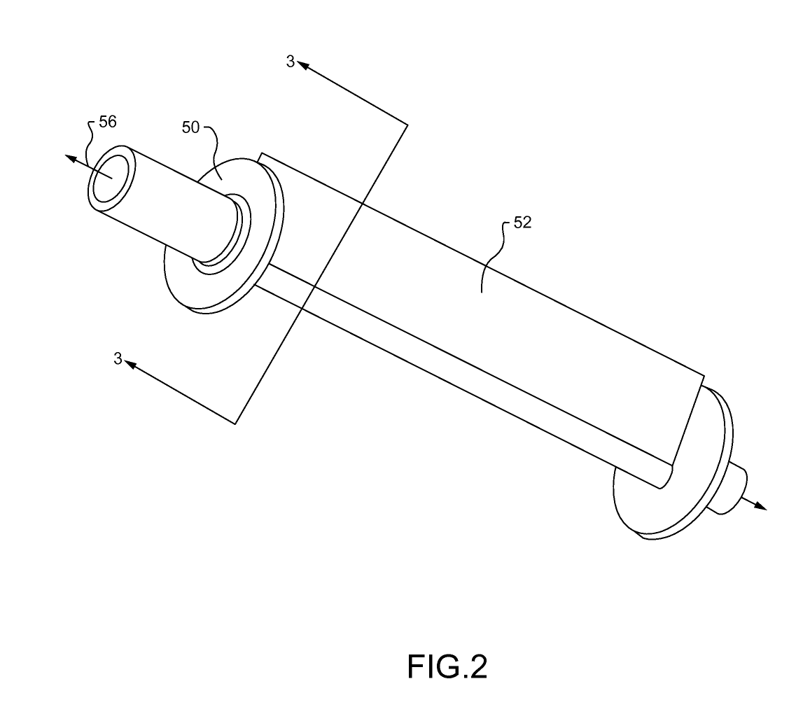

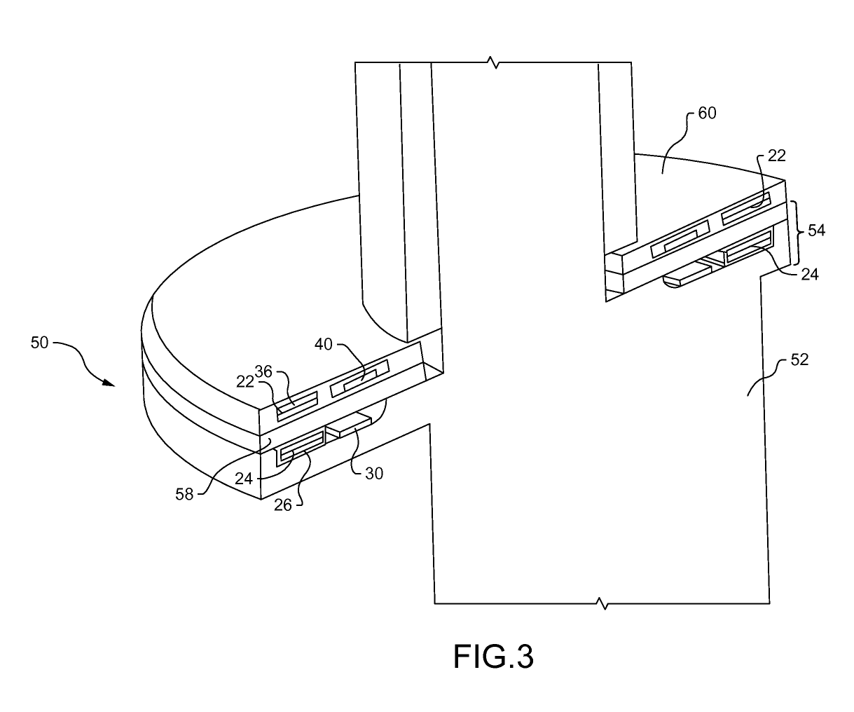

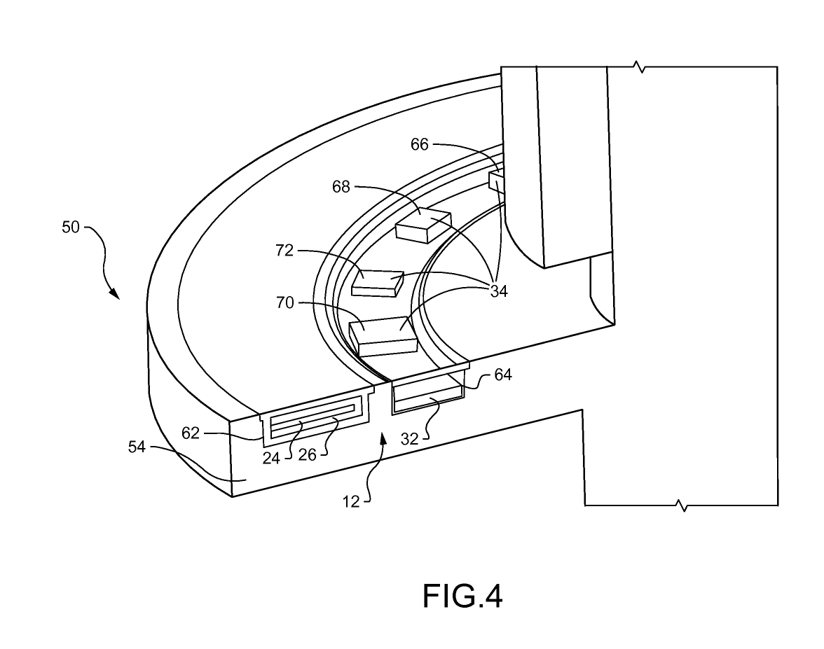

Turning now to FIGS. 2-3, an example application of the sensing system 10 is depicted, according to an embodiment. For example, the sensing system 10 may be incorporated into a base 50 of an airfoil 52, such as a gas turbine engine airfoil. While the example of an airfoil is given, it is to be understood that the teachings of this disclosure can be employed with equal efficacy with many other parts of a gas turbine engine, as well as many other parts inside and outside the aerospace industry. The airfoil 52 and a lower disk 54 of the base 50 may be connected and may rotate together about a central axis 56 of the airfoil 52 (see FIG. 3). The lower disk 54 may be metallic and may have the sensing device 12 embedded therein. For example, the core assembly 26 and the sensing platform 30 of the sensing device 12 may be placed in one or more annular cavities of the lower disk 54 (see FIG. 4 and further details below) and the cavity may be covered by a cover 58, such as a metallic cover, by additive manufacturing. Likewise, the reader device 16, including the core assembly 36 and the circuit platform 40, may be embedded in one or more annular cavities of a stationary upper disk 60 of the base 50 and may be powered by batteries or hard wires (not shown). The upper disk 60 may be metallic, and the reader device 16 may be embedded in the upper disk 60 by additive manufacturing or another suitable method. The primary magnetic coil 22 and the secondary magnetic coil 24 may magnetically couple through low frequency electromagnetic fields (on the order of hundredths of a kilohertz) that penetrate the metallic material (or other material) of the upper disk 60 and the lower disk 54 (including the cover 58), allowing the transfer of power and data therebetween. In this way, the lower disk 54/airfoil 52 may rotate freely as the need for attachment of batteries and/or hard wires to the lower disk 54 to power and collect data from the sensing device 12 may be eliminated.

FIG. 4 depicts one possible arrangement of the sensing device 12 in the rotatable lower disk 54 with the cover 58 and the upper disk 60/reader device 16 removed for clarity. The core assembly 26 may be placed in a first annular cavity 62 of the lower disk 54, and the sensing platform 30 including the PCB 32 and the ICs 34 may be placed in a second annular cavity 64 of the lower disk 54. The annular cavities 62 and 64 may span 360° around the base 50. As an example, the ICs 34 may include an accelerometer 66 that measures the proper acceleration/g-force of the airfoil 52, one or more thermocouple interface ICs 68, a microcontroller 70, and a low frequency radio frequency identification (LF RFID) IC 72 for interfacing between the coils 22 and 24 and the microcontroller 70, among other possibilities. In alternative arrangements, the core assembly 26 and the sensing platform 30 may be placed in the same cavity. In addition, it will be understood that the cavities 62 and 64 may not be annular in some arrangements and may have alternative shapes. It is also noted that the components of the reader device 16 (the core assembly 36 and the circuit platform 40) may be distributed in similar annular cavities of the upper disk 60.

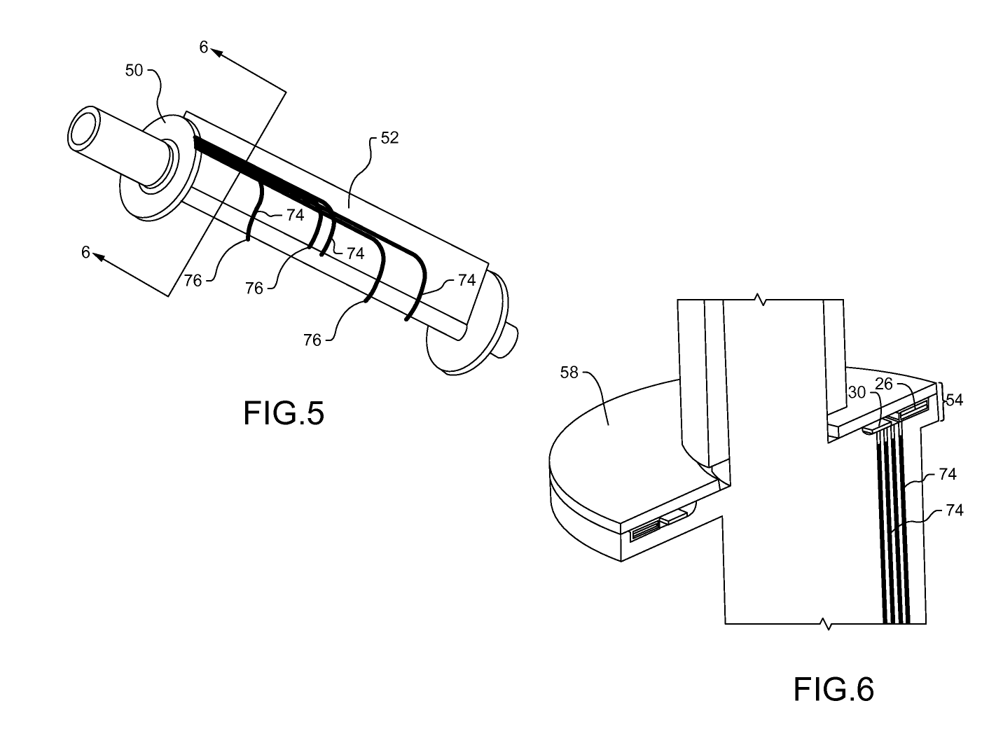

Turning now to FIGS. 5-6, an example in which several thermocouples 74 are embedded in the airfoil 52 is shown. Each of the thermocouples 74 may terminate at a tip 76 where a temperature measurement is made. In particular, the tips 76 of the thermocouples 74 may be positioned at various locations along the airfoil 52 to allow temperature measurements at different points of interest along the airfoil. The thermocouples 74 may connect to one or more thermocouple interface ICs 68 embedded in the lower disk 54 (see FIGS. 4 and 6) to allow for low frequency wireless communication of the collected temperature data to the reader device 16 as described above.

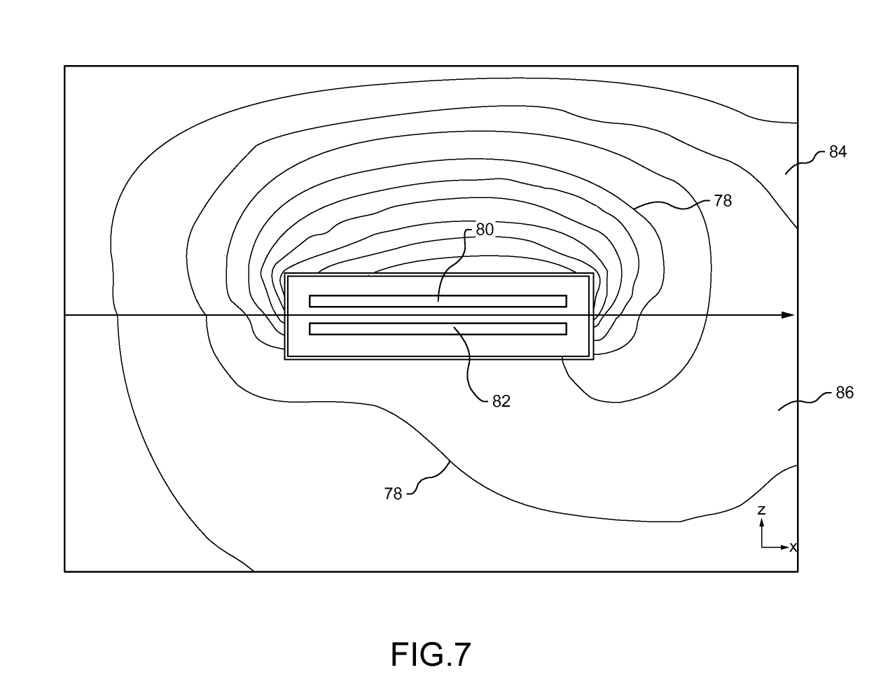

FIG. 7 depicts a simulation of a magnetic flux linkage 78 between a primary magnetic coil 80 and a secondary magnetic coil 82 embedded in separate metal parts 84 and 86 with an air gap between the coils 80 and 82. There is an increase in power loss for power transmission from the primary coil 80 to the secondary coil 82 with increasing thickness of the parts 84 and/or 86, due to decreased magnetic coupling through the magnetic flux linkage 78.

Several design considerations may be used to optimize the magnetic coupling and wireless communication between the primary and secondary magnetic coils of the sensing system 10 disclosed herein. For example, to increase the magnetic coupling between the primary magnetic coil 22 and secondary magnetic coil 24, the separation distance between the coils 22 and 24 may be reduced and/or the thickness of the parts 14 and/or 18 may be reduced. Alternatively, the size of the magnetic cores may be increased to increase coupling area without changing the separation distance or the thickness of the parts. As another alternative, the type of metals or other materials used for the parts 14 and/or 18 may be varied to improve magnetic coupling. For instance, higher resistivity metallic materials may improve magnetic coupling between the coils 22 and 24 by lowering the Eddy effect.

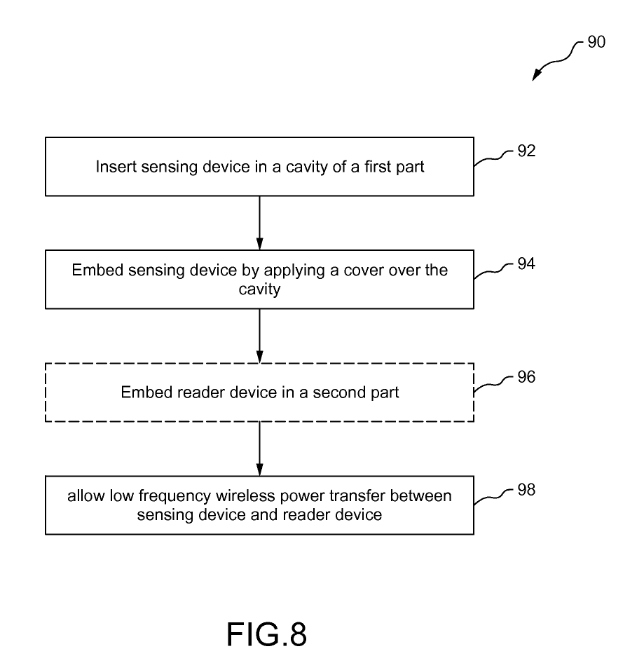

A method 90 that may be involved in the manufacture of the sensing system 10 are shown in FIG. 8. Beginning with a first block 92, the components of the sensing device 12, including the core assembly 26 and the sensing platform 30, may be inserted in one or more cavities of the first part 14 (see, for example, the cavities 62 and 64 of FIG. 4). The cavity may have an open top to allow the insertion of the components of the sensing device 12 therein. The sensing device 12 may then be embedded in the part 14 by applying a cover over the cavity according to a next block 94 (see, for example, the cover 58 of FIG. 3). In particular, the block 94 may be carried out by forming the cover over the cavity and the sensing device 12 by additive manufacturing. Suitable additive manufacturing techniques may include, but are not limited to, direct metal laser sintering (DMLS), laser engineered net shaping (LENS), and cold spray additive manufacturing. Optionally, the reader device 16 may be embedded in the same part 14 as the sensing device 12 or a second part 18 according to a block 96. Similar to the embedment of the sensing device 12, the reader device 16 may be embedded in the part 14 or 18 by placing the components of the reader device 16 (the core assembly 36 and the sensing platform 40) in one or more cavities of the part and covering the cavity/cavities with a cover by additive manufacturing. Alternatively, the reader device 16 may remain exposed to air. It will be understood that the blocks 94 and 96 may be performed simultaneously or in a different order from that shown in FIG. 8.

The method may further involve allowing low frequency wireless power transfer between the sensing device 12 and the reader device 16 according to a next block 98. As explained above, the low frequency wireless power transfer may be provided by a magnetic flux linkage between the primary magnetic coil 22 of the reader device 16 and the secondary magnetic coil 24 of the sensing device 12. The low frequency wireless power transfer may permit wireless power transfer from the reader device 16 to the sensing device 12, as well as wireless data transfer (e.g., sensing data, etc.) between the reader device 16 and the sensing device 12 over the non-contact wireless interface 20.

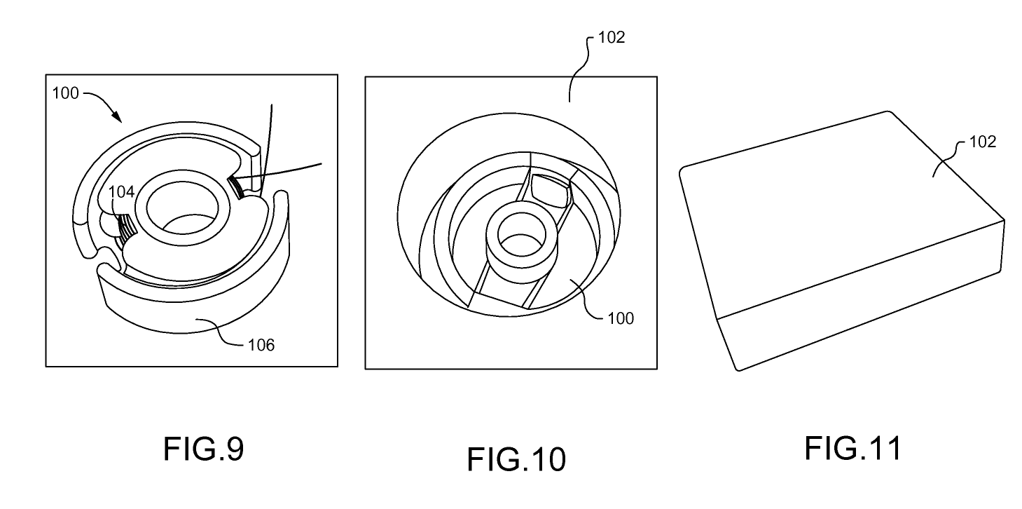

Pictures of some of the steps of the method 90 using an exemplary magnetic core assembly 100 and metallic part 102 are depicted in FIGS. 9-11. Specifically, FIGS. 9-11 depict an embedment of the core assembly 100 in the metallic part 102 using additive manufacturing. FIG. 9 shows the core assembly 100, including a magnetic coil 104 in a ferrite core 106, prior to embedment in the metallic part 102. FIG. 10 shows the metallic part 102 after placement of the core assembly 100 in a cavity of the metallic part 102, while FIG. 11 shows the metallic part 102 after covering the cavity and the core assembly 100 with a metallic cover by additive manufacturing. As can be seen from FIG. 11, the core assembly 100 is completely enclosed in the metallic part 102 and is not at all visible from the surface of the part 102. Thus, additive manufacturing provides an effective technique for permanently embedding and protecting sensing components in metallic parts.

### INDUSTRIAL APPLICABILITY

In general, it can therefore be seen that the technology disclosed herein has industrial applicability in a variety of settings such as, but not limited to, industrial applications that use digital or analog sensors. The sensing system disclosed herein leverages additive manufacturing to embed a sensing device within a part of interest, thereby protecting the components/electronics of the sensing device from wear caused by environmental exposure. This may reduce the need for any future maintenance and extend the usage of the sensing system beyond temporary testing and diagnostics. In addition, the sensing system disclosed herein also includes a reader device that may be configured to power up and exchange data with the sensing device over a non-contact wireless interface via low frequency wireless power transfer that penetrates the material of the part. Specifically, the reader device and the sensing device may each include a magnetic coil that produces tightly focused, low frequency electromagnetic fields that couple through metallic layers (or other types of material layers) and allow the low frequency wireless power transfer across the non-contact interface, even when both the reader device and the sensing are completely covered by the material of a part. As the reader device may be stationary or embedded in a stationary part, it may be powered and electrically connected to a control center with batteries and/or hard wires. This allows the sensing device to be powered and the exchange of digital data with the sensing device without the need for hard wires that could become cumbersome or entangled, particularly if the sensing device is embedded in a moving or rotating part. For example, as disclosed herein, temperature data from an array of thermocouples embedded in an airfoil may be measured across a rotating interface without wires. The sensing system disclosed herein may also enable digital transfer of data across non-contact wireless interfaces so as to avoid all of the environmental impacts of an analog interface. It is expected that the technology disclosed herein may find wide industrial applicability in a wide range of areas such as, but not limited to, aerospace and automotive applications.

What is claimed is:

1. A sensing system, comprising:
a reader device including a primary magnetic coil;
a sensing device including a secondary magnetic coil and a sensing platform configured to acquire sensing data; and
a first part having the sensing device embedded therein, the reader device and the sensing device being configured to communicate over a non-contact wireless interface using low frequency wireless power transfer.

2. The sensing system of claim 1, wherein the sensing device is embedded in the first part by additive manufacturing.

3. The sensing system of claim 2, wherein the first part is a metallic part.

4. The sensing system of claim 3, wherein the reader device is embedded in a second part.

5. The sensing system of claim 3, wherein the low frequency wireless power transfer is provided by a magnetic flux linkage between the primary magnetic coil and the secondary magnetic coil, and wherein the magnetic flux linkage penetrates through the first part.

6. The sensing system of claim 4, wherein the first part is a non-stationary part, and wherein the second part is a stationary part.

7. The sensing system of claim 3, wherein the reader device is configured to power the sensing device through the low frequency wireless power transfer.

8. The sensing system of claim 7, wherein the low frequency wireless power transfer permits wireless data transfer between the sensing device and the reader device.

9. The sensing system of claim 8, wherein the sensing device is configured to transmit the sensing data to the reader device by the low frequency wireless power transfer.

10. The sensing system of claim 9, wherein the sensing platform includes a printed circuit board (PCB) supporting a plurality of integrated circuits (ICs), and wherein at least one of the ICs is a sensor.

11. The sensing system of claim 10, wherein the sensor is configured to detect at least one property associated with the first part, and wherein the at least one property is selected from temperature, g-force, strain, and angular position.

12. A sensing system, comprising:
a reader device including a primary magnetic coil;
a sensing device including a secondary magnetic coil and a sensing platform configured to acquire sensing data;
a stationary part supporting the reader device; and
a rotatable part having the sensing device embedded therein, the reader device and the sensing device being configured to communicate over a non-contact wireless interface using low frequency wireless power transfer.

13. The sensing system of claim 12, wherein the sensing device is embedded in the rotatable part by additive manufacturing.

14. The sensing system of claim 13, wherein the rotatable part is a metallic part.

15. The sensing system of claim 14, wherein the reader device is embedded in the stationary part by additive manufacturing.

16. The sensing system of claim 14, wherein the low frequency wireless power transfer is provided by a magnetic flux linkage between the primary magnetic coil and the secondary magnetic coil, and wherein the magnetic flux linkage penetrates through the stationary part and the rotatable part.

17. The sensing system of claim 16, wherein the reader device is powered by a battery or with hard wires.

18. The sensing system of claim 17, wherein the reader device is configured to power the sensing device through the low frequency wireless power transfer.

19. The sensing system of claim 18, wherein the low frequency wireless power transfer permits wireless data transfer between the sensing device and the reader device.

20. A method for manufacturing a sensor system, comprising:
inserting a sensing device in a cavity of a part, the sensing device including a secondary magnetic coil and a sensing platform configured to acquire sensing data; and
applying a cover over the cavity and the sensing device by additive manufacturing to provide an embedded sensing device;
wherein a reader device and the embedded sensing device communicate over a non-contact wireless interface using low frequency wireless power transfer.
